(19) United States
(12) Patent Application Publication
(10) Pub. No.: US 2014/0042391 A1
(43) Pub. Date: Feb. 13, 2014

(54) SEMICONDUCTOR DEVICE AND METHOD OF MANUFACTORING THE SAME

(71) Applicant: SAMSUNG ELECTRONICS CO., LTD., Suwon-Si (KR)

(72) Inventors: Jun-youn KIM, Hwaseong-si (KR); Joo-sung KIM, Seongnam-si (KR); Young-jo TAK, Hwaseong-si (KR)

(73) Assignee: SAMSUNG ELECTRONICS CO., LTD., Suwon-Si (KR)

(21) Appl. No.: 13/839,693

(22) Filed: Mar. 15, 2013

(30) Foreign Application Priority Data
Aug. 9, 2012 (KR) 10-2012-0087352

(51) Int. Cl. H01L 29/20; H01L 29/15

(52) U.S. Cl. CPC H01L 29/2003; H01L 29/15
USPC 257/22

(57) ABSTRACT

A semiconductor device includes a first coalescent layer, a second coalescent layer, a nitride stacked structure on the second coalescent layer, and a third layer between the first and second coalescent layers. The first coalescent layer includes a plurality of formations that are partially merged, and the third layer is disposed on the formations to allow a first type of stress to be generated in an area which includes the first coalescent layer and a second type of stress to be generated in an area which includes the second coalescent layer.

### CROSS-REFERENCE TO RELATED APPLICATIONS

This application claims the benefit of Korean Patent Application No. 10-2012-0087352, filed on Aug. 9, 2012, in the Korean Intellectual Property Office, the disclosure of which is incorporated herein in its entirety by reference.

### BACKGROUND

1. Field

The present disclosure relates to semiconductor devices and methods for manufacturing semiconductor devices.

2. Description of the Related Art

Many nitride-based semiconductor devices use sapphire substrates that are more expensive, more difficult to process, and/or have lower electric conductivity. Also, when a sapphire substrate is epitaxially grown to a larger size, the substrate may bend at higher temperatures due to a lower thermal conductivity. Consequently, it is more difficult to make sapphire substrates larger in size.

Semiconductor devices which use silicon substrates have been proposed in order to avoid some of these drawbacks. Because silicon has a higher thermal conductivity than sapphire, a substrate made of silicon will not bend as much even at temperatures required for growing nitride thin films. Accordingly, silicon substrates may be more suitable for making larger devices that use nitride thin films.

However, the approach of using silicon substrates in nitride-based devices is not without drawbacks. For example, when growing a nitride thin film on a silicon substrate, dislocation density may be increased due to a disparity between lattice constants of the substrate and the thin film. Also, cracks may occur due to differences in thermal expansion coefficients.

It has generally been observed that a tradeoff exists between reducing dislocation density and preventing cracks. For example, reducing dislocation density may generate an increase in tensile stress, which may result in the formation of cracks. On the other hand, techniques used to prevent cracks may not produce a sufficient reduction in dislocation density.

### SUMMARY

In accordance with example embodiments, a semiconductor device comprising a first coalescent layer, a second coalescent layer, a nitride stacked structure on the second coalescent layer, and a third layer between the first and second coalescent layers. The first coalescent layer includes a plurality of formations that are partially combined, and the third layer may be disposed on the formations to allow a first type of stress to be generated in an area which includes the first coalescent layer and a second type of stress to be generated in an area which includes the second coalescent layer.

The first type of stress may be opposite to the second type of stress. The first type of stress may be tensile stress and the second type of stress may be compressive stress. In example embodiments, the first and second stresses may be different levels of tensile stress, with the second coalescent layer receiving the lesser of the two stresses.

Additionally, the third layer may be made of a material including a metal and the metal may be, for example, at least one of aluminum or gallium. Also, the third layer may be made of a material that includes nitride. Also, the third layer may be in direct or indirect contact with the first and second coalescent layers. Also, the nitride stacked structure may be in direct or indirect contact with the second coalescent layer.

Additionally, a first surface of the first coalescent layer may have an uneven surface as a result of the partially merged formations, and the third layer may have an uneven surface as a result of the uneven first surface of the first coalescent layer. Also, the first coalescent layer may have a first thickness and the second coalescent layer may have a second thickness less than the first thickness.

Additionally, the semiconductor device may include a mask layer, where the third layer faces a first surface of the first coalescent layer and the mask layer faces a second surface of the first coalescent layer, and where the partially merged formations of the first coalescent layer contacting a pattern of the mask layer. The mask layer may be between a nitride layer and the first coalescent layer.

Additionally, the semiconductor device may include a fourth layer between the second coalescent layer and the nitride stacked structure, wherein the fourth layer is made of a metal or metal alloy. The metal or metal alloy may include at least one of aluminum, gallium, or a lanthanide. Also, the semiconductor device may include a third coalescent layer between the second coalescent layer and the nitride stacked structure and a fourth layer between the second and third coalescent layers. The third and fourth layers may be made of a material including at least one of a metal or nitride.

Additionally, the semiconductor material may include a nuclear growth layer; a buffer layer between the first coalescent layer and the nuclear growth layer; and a silicon substrate on the nuclear growth layer.

In accordance with example embodiments, a semiconductor device includes a first nitride semiconductor layer, a mask layer on the first nitride semiconductor layer, a first coalescent layer forming islands that are grown and merged according to patterns of the mask layer and having an uneven upper surface; an insertion layer on the first coalescent layer, a second coalescent layer on the insertion layer, and a nitride stacked structure on the second coalescent layer.

The mask layer may include a silicon nitride material or a magnesium nitride material, and the first and second coalescent layers may be formed of a nitride semiconductor.

Also, the first and second coalescent layers may be formed of a nitride material including gallium. In accordance with example embodiments, the first and second coalescent layers may be formed of AlₓIn_{y}Ga_{1-x-y}N (0≦x, y≦1, x+y<1), and the insertion layer may be formed of a material selected from the group consisting of Alₓ₀In_{y0}Ga_{1-x0-y0}N (0≦x0, y0≦1, x0+y0≦1), step-grade AlₓIn_{y}Ga_{1-x-y}N (0≦x, y≦1, x+y≦1), and Alₓ₁In_{y1}Ga_{1-x1-y1}N/Alₓ₂In_{y2}Ga_{1-x2-y2}N (0≦x1, x2, y1, y2≦1, x1≠x2 or y1≠y2) super lattice. The insertion layer may generate a compressive stress, and an uneven upper surface may be formed before the merging operation is finished.

The semiconductor device may further include at least one buffer layer under the first nitride semiconductor layer. The at least one buffer layer may be formed of a material including one selected from the group consisting of AlN, AlGaN, step-grade AlₓIn_{y}Ga_{1-x-y}N (0≦x, y≦1, x+y≦1), and a Alₓ₁In_{y1}Ga_{1-x1-y1}N/Alₓ₂In_{y2}Ga_{1-x2-y2}N (0≦x1, x2, y1, y2≦1, x1≠x2 or y1≠y2, x1+y1≦1, x2+y2≦1) super lattice.

The semiconductor device may further include a nuclear growth layer under the at least one buffer layer. The nuclear growth layer may be formed of AlN or another material.

The semiconductor device may further include a substrate under the nuclear growth layer. The substrate may include a silicon substrate or a silicon carbide substrate.

The semiconductor device may further include at least one pair of an insertion layer and a coalescent layer between the second coalescent layer and the nitride stacked structure.

The semiconductor device may further include an intermediate layer between the second coalescent layer and the nitride stacked structure. The intermediate layer may be formed of one selected from the group consisting of Alₓ₀In_{y0}Ga_{1-x0-y0}N (0≦x0, y0≦1, x0+y0≦1), step-grade AlₓIn_{y}Ga_{1-x-y}N (0≦x, y≦1, x+y≦1), and a Alₓ₁In_{y1}Ga_{1-x1-y1}N/Alₓ₂In_{y2}Ga_{1-x2-y2}N (0≦x1, x2, y1, y2≦1, x1≠x2 or y1≠y2) super lattice.

The nitride stacked structure may include a plurality of nitride semiconductor layers and at least one intermediate layer between the plurality of nitride semiconductor layers.

In accordance with example embodiments, a method of manufacturing a semiconductor device includes forming a first nitride semiconductor layer on a substrate, forming a mask layer on the first nitride semiconductor layer, forming a first coalescent layer according to patterns of the mask layer, forming an uneven upper surface of the first coalescent layer by suspending the coalescence before the coalescence of the first coalescent layer is finished, forming an insertion layer on the uneven upper surface, forming a second coalescent layer on the insertion layer, and forming a nitride stacked structure on the second coalescent layer.

### BRIEF DESCRIPTION OF THE DRAWINGS

FIG. 1A shows an example embodiment of a semiconductor device, and FIG. 1B shows one way a coalescent layer may be formed.

FIG. 2 shows another example embodiment of a semiconductor device.

FIG. 3 shows an example embodiment of a semiconductor device including an intermediate layer.

FIG. 4 shows an example embodiment of a semiconductor device including a nitride stacked substrate.

FIG. 5 shows an example embodiment in which layers including a substrate are formed in the semiconductor device of FIG. 1A.

FIG. 6 shows another example embodiment of a semiconductor device.

FIG. 7 shows a cross-sectional image of the device of FIG. 6.

FIG. 8 shows a semiconductor device different from the FIG. 6 device.

FIG. 9 compares curvature rates and reflectivities of the devices shown in FIG. 6 and FIG. 8.

FIG. 10 compares stress distributions measured for an example embodiment of a semiconductor device and another device with no insertion layer.

FIG. 11 compares delta bowing and maximum crack length for an example embodiment of a semiconductor device and another device.

FIGS. 12 through 18 show various stages included in an example embodiment of a method of manufacturing a semiconductor device.

### DETAILED DESCRIPTION OF EXAMPLE EMBODIMENTS

The present disclosure will now be described more fully hereinafter with reference to the accompanying drawings, in which various example embodiments are shown. The examples may, however, be embodied in different forms and should not be construed as limited to the example embodiments set forth herein. Rather, these embodiments are provided so that this disclosure will be more thorough and complete, and will fully convey the scope of the disclosure to those skilled in the art. The same reference numbers indicate the same components throughout the specification. In the attached figures, the thickness of layers and regions may have been exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure.

The use of the terms “a” and “an” and “the” and similar referents in the disclosure (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this disclosure belongs. It is noted that the use of any and all examples provided herein is intended merely to better illuminate the various embodiments and is not a limitation on the scope of the disclosure unless otherwise specified. Further, unless defined otherwise, all terms defined in generally used dictionaries should not be overly interpreted.

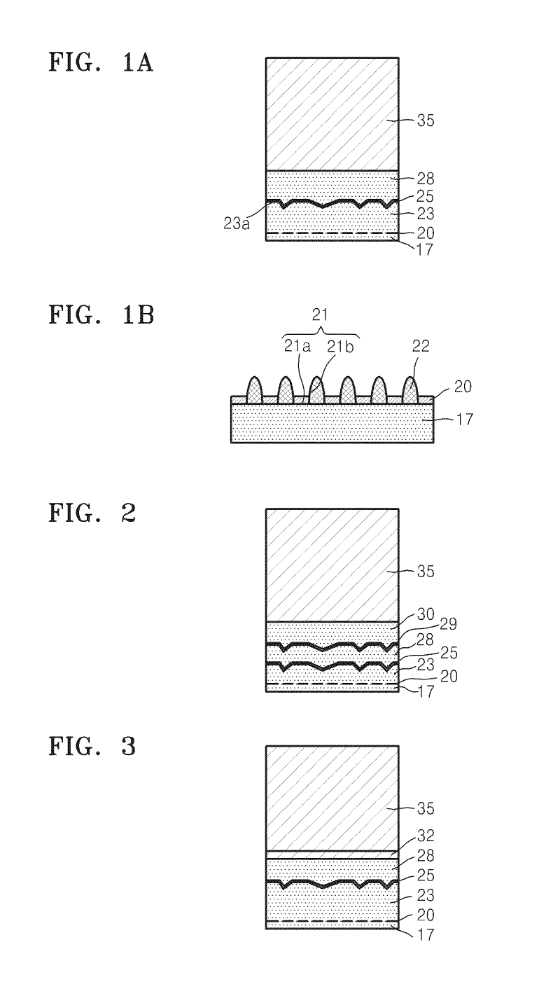

FIG. 1A shows, in cross-section, an example embodiment of a semiconductor device that includes a first nitride semiconductor layer 17, a mask layer 20 on the first nitride semiconductor layer 17, and a first coalescent layer 23 on the mask layer 20. The first coalescent layer 23 may be formed, for example, by being horizontally grown according to one or more patterns of the mask layer.

The mask layer may be randomly distributed using various process of which metal organic chemical vapor deposition (MOCVD) process is an example. In FIG. 1A, the mask layer is shown to have one or more regular patterns. However, in alternative embodiments, the mask layer may include a non-uniform or other pattern different from the one shown.

In terms of materials, the mask layer 20 may be formed, for example, of silicon nitride (SiNx) or magnesium nitride (MgNx). In one specific application, a SiNx mask layer may be formed by using SiH₄ (silane) and an ammonia gas. In other embodiments, a different material and/or different process may be used to form the mask layer.

FIG. 1B shows an example of a process of forming the first coalescent layer 23 using mask layer 20. In this example, the mask layer may have a number of patterns 21, each including a masking region 21a that partially covers the first nitride semiconductor layer 17 and an open region 21b that partially exposes the first nitride semiconductor layer 17. In this embodiment, the masking regions are formed on the semiconductor layer in an alternating pattern.

Exposed portions of the first nitride semiconductor layer 17 may be determined according to coverage of the mask layer 20 on the first nitride semiconductor layer. As a result, growth types of islands 22 grown on the first nitride semiconductor layer 17 may vary. For example, if the exposed area (corresponding to the open region) of the first nitride semiconductor layer is reduced by increasing the masking region of the SiN_{X}, the density of initial islands that will be grown on the mask layer 20 is reduced, while a coalescent island may be increased. In this case, a thickness of a coalescent layer may be increased, too.

The first coalescent layer 23 may be formed, for example, of a nitride semiconductor, and the islands 22 are formed on respective open regions 21b according to the patterns of the mask layer 20. During this formation process, the islands 22 merge with each other while growing laterally to form the first coalescent layer 23. In an example embodiment, growth of the first coalescent layer 23 may be stopped before the merging operation is finished and, thus, the first coalescent layer 23 may have an uneven upper surface 23a.

An insertion layer 25 is disposed on the uneven upper surface 23a, and a second coalescent layer 28 is disposed on the insertion layer 25. In addition, a nitride stacked structure 35 including at least one nitride semiconductor layer may be disposed on the second coalescent layer 28.

The insertion layer 25 is disposed between the first coalescent layer 23 and the second coalescent layer 28 to generate a compressive stress. The insertion layer 25 may be formed of material containing a metal or a nitride. According to one example, insertion layer may be made from a material that includes one or more selected from the group consisting of Alₓ₀In_{y0}Ga_{1-x0-y0}N (0≦x0, y0≦1, x0+y0≦1), step-grade AlₓIn_{y}Ga_{1-x-y}N (0≦x, y≦1, x+y≦1), and a Alₓ₁In_{y1}Ga_{1-x1-y1}N/Alₓ₂In_{y2}Ga_{1-x2-y2}N (0≦x1, x2, y1, y2≦1, x1≠x2 or y1≠y2) super lattice, wherein “ln” refers to a lanthanide.

The second coalescent layer 28 may be grown until the merging is finished on the insertion layer 25. In an example embodiment, the merging of the second coalescent layer 28 may be completely performed so that there is an even or uniform upper surface. In an example embodiment, the upper surface may have a texture or roughness, for example, in order to accommodate or promote adherence of one or more additional layers prior to formation of the nitride stacked substrate. When an even or uniform upper surface is formed, the nitride stacked structure 35 may be formed on the even (e.g., planarized) second coalescent layer 28.

This example embodiment has only one insertion layer, which, as shown, is disposed between the first coalescent layer 23 and second coalescent layer 28. In other example embodiments, a plurality of insertion layers may be formed, for example, when more than two coalescent layers are to be included.

FIG. 2 shows an example embodiment that has two insertion layers and three coalescent layers. In this example embodiment, the first coalescent layer 23, the insertion layer 25, and the second coalescent layer 28 may be stacked. Then, another insertion layer 29 is formed on the second coalescent layer 28 and a third coalescent layer 30 is disposed on the coalescent layer 29. In forming this structure, the second coalescent layer 28 may be in a state where the merging operation is not completely finished yet. In this case, the second coalescent layer 28 may have an uneven upper surface. In other example embodiments, the second coalescent layer may be completely merged.

In the example of FIG. 2, an insertion layer is disposed between each adjacent pair of the coalescent layers. The first, second, and third coalescent layers 23, 28, and 30 may be formed, for example, of a nitride semiconductor, e.g., a nitride material including gallium. The first, second, and third coalescent layers 23, 28, and 30 may be formed of AlₓIn_{y}Ga_{1-x-y}N (0≦x, y≦1, x+y<1). For example, the first, second, and third coalescent layers may be formed of a material including at least one of GaN, InGaN, or AlInGaN.

FIG. 3 shows an example embodiment in which an intermediate layer 32 is disposed between the second coalescent layer 28 and the nitride stacked structure 35 in FIG. 1. The intermediate layer 32 may compensate for a relative tensile stress generated by the nitride stacked structure 35, thereby reducing generation of cracks due to the tensile stress when growing the nitride stacked structure 35. The intermediate layer 32 may be formed of one selected from the group consisting of Alₓ₀In_{y0}Ga_{1-x0-y0}N (0≦x0, y0≦1, x0+y0≦1), step grade AlₓIn_{y}Ga_{1-x-y}N (0≦x, y≦1, x+y≦1), and a Alₓ₁In_{y1}Ga_{1-x1-y1}N/Alₓ₂In_{y2}Ga_{1-x2-y2}N (0≦x1, x2, y1, y2≦1, x1≠x2 or y1≠y2) super lattice.

In accordance with the example embodiments disclosed herein, the nitride stacked structure 35 may include at least one nitride semiconductor layer. The at least one nitride semiconductor layer may be formed of, for example, a nitride material including gallium. The at least one nitride semiconductor layer may be formed of AlₓIn_{y}Ga_{1-x-y}N (0≦x, y≦1, x+y<1). For example, the at least one nitride semiconductor layer may be formed of a material including at least one of GaN, InGaN, or AlInGaN. In other embodiments, the at least one nitride semiconductor layer may be formed of a nitride material that does not include aluminum. In addition, when the nitride stacked structure 35 includes a plurality of nitride semiconductor layers, one or more intermediate layers may be disposed between the nitride semiconductor layers.

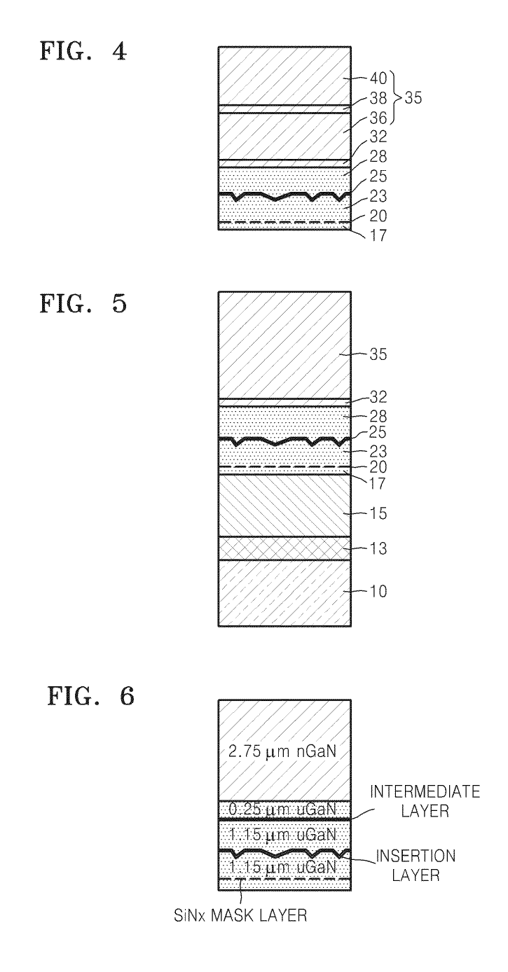

FIG. 4 shows an example embodiment having a nitride stacked structure 35 which includes a second nitride semiconductor layer 36, an intermediate layer 38, and a third nitride semiconductor layer 40. (The first nitride semiconductor layer corresponds to reference numeral 17). The nitride semiconductor layers may be undoped or doped in any combination.

For example, among the plurality of nitride semiconductor layers, the one nitride semiconductor layer may be doped as n-type or p-type and the other nitride semiconductor layers may be undoped. Alternatively, two or more of the three nitride semiconductor layers may be doped or undoped. Also, in this example, the third nitride semiconductor layer 40 may be formed as a conductive nitride layer doped with n-type or p-type impurities. In other embodiments, the third nitride semiconductor layer 40 may include a dual-layered structure including an updoped layer and a doped layer.

Additionally, the third nitride semiconductor layer 40 may have, for example, a thickness of 2 μm or greater and a doping density of 3E18/cm3 or greater in consideration of current spreading in the semiconductor device. In other embodiments, layer 40 may have a different thickness and/or doping density. Moreover, the structure of the nitride stacked structure 35 may be different in terms of numbers of nitride layers, thicknesses, doping materials, doping densities, or a combination thereof.

FIG. 5 shows another embodiment which includes a substrate 10 disposed under the first nitride semiconductor layer 17. In addition, a nuclear growth layer 13 and at least one buffer layer 15 may be disposed between the substrate 10 and the first nitride semiconductor layer 17. The first nitride semiconductor layer 17 may be formed on the at least one buffer layer 15. The first nitride semiconductor layer 17, and the mask layer 20, the first coalescent layer 23, the insertion layer 25, the second coalescent layer 28, the intermediate layer 30, and the nitride stacked structure 35 formed on the first nitride semiconductor layer 17 may be the same as those in FIG. 3. Alternatively, one or more of these layers may be omitted or different from the structure in FIG. 3.

In an example embodiment, substrate 10 may be formed of a material including silicon, i.e., substrate 10 may be a silicon-based substrate. For example, substrate 10 may include a silicon (Si) substrate or a silicon carbide (SiC) substrate. The silicon substrate may use, for example, a (111) surface. The substrate 10 may be cleaned using sulfuric acid in oxygenated water, hydrofluoric acid, or a deionized aqueous suspension. After cleaning, impurities such as metal and organic materials and a native oxide film on the cleaned substrate 10 (if formed) may be removed, and a surface of the cleaned substrate 10 is terminated as hydrogen to be suitable for epitaxial growth.

The nuclear growth layer 13 may be formed of, for example, AlN. The nuclear growth layer 13 may prevent a melt-back phenomenon from being generated when the substrate 10 and the nitride semiconductor layer react with each other, and may also make the buffer layer 15 or the first nitride semiconductor layer 17 that will be grown later sufficiently wet nuclear. In a process of growing the nuclear growth layer, Al source may initially be injected in order to prevent the substrate from being exposed to ammonia and being nitrated. In an example embodiment, the nuclear growth layer may have a thickness of tens to hundreds of nanometers.

The at least one buffer layer may be formed of a material including one selected from the group consisting of AlN, AlGaN, step grade AlₓIn_{y}Ga_{1-x-yN} (0≦x, y≦1, x+y≦1), and a Alₓ₁In_{y1}Ga_{1-x1-y1}N/Alₓ₂In_{y2}Ga_{1-x2-y2}N (0≦x1, x2, y1, y2≦1, x1≠x2 or y1≠y2, x1+y1≦1, x2+y2≦1) super lattice. The at least one buffer layer 15 may be formed, for example, to reduce the dislocation caused a disparity between the lattice constants of substrate 10 and first nitride semiconductor layer 17, and/or to restrain generation of cracks due to a disparity between the thermal expansion coefficients of substrate 10 and first nitride semiconductor layer 20. In the embodiment of FIG. 5, one buffer layer 15 is formed on substrate 10; however, a plurality of buffer layers may be formed in other embodiments.

During processing, a dislocation loop may form at an interface between the buffer layer 15 and the first nitride semiconductor layer 17. This loop may reduce dislocation density of the structure. If buffer layer 15 is formed of AlₓGa₁₋ₓN (0≦x≦1), Al composition may be constant or may be gradually reduced. For example, the Al composition may be reduced gradually from Al_{0.7}Ga_{0.3}N to Al_{0.5}Ga_{0.5}N and to Al_{0.3}Ga_{0.7}N in step-grades. In this case, the disparity between the lattice constants and the thermal expansion coefficients of the buffer layer 15 and the nitride semiconductor layer is gradually reduced and, accordingly, the compressive stress may be efficiently generated during the epitaxial growth operation and the tensile stress generated during the cooling down operation may be reduced. Also, under these conditions, bending of threading dislocation may be generated to reduce defects.

As the thickness of the buffer layer 15 increases, compressive stress relaxation of the first nitride semiconductor layer may be reduced and defects may also be reduced. In one exemplary application, the buffer layer 15 may be hundreds to a few nanometers in thickness. Meanwhile, the substrate 10 may be removed while manufacturing or after manufacturing the semiconductor device. When or after the substrate 10 is removed, the nuclear growth layer 13 and the buffer layer 15 may be removed together. Alternatively, these layers may be separately removed using any one of a variety of processing techniques.

One example technique for removing substrate 10 involves bonding a wafer (not shown) to an upper portion of the nitride stacked structure 35 as a supporter. (Wafer bonding is described in greater detail below in connection with the method embodiments).

When additional tensile stress is generated due to bonding metal during the wafer bonding process and the tensile stress is equal to or greater than fracture toughness of the nitride semiconductor thin film, cracks may occur in the nitride semiconductor thin film. In addition, when the substrate is removed, the tensile stress generated due to the bonding metal causes tensile stress in the nitride semiconductor thin film, which may also promote the generation of cracks.

In accordance with one or more embodiments described herein, cracks in the nitride semiconductor thin film may be prevented or reduced during the substrate removal process.

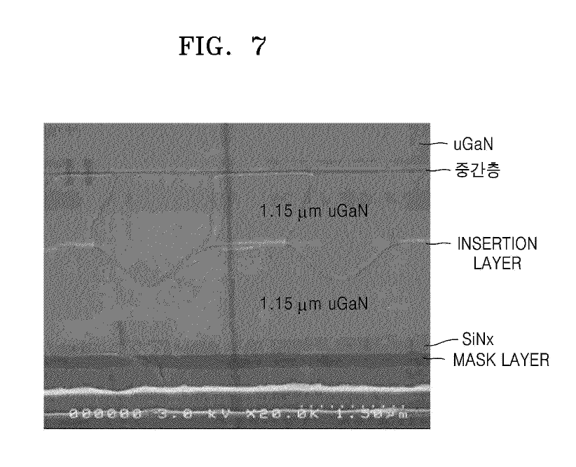

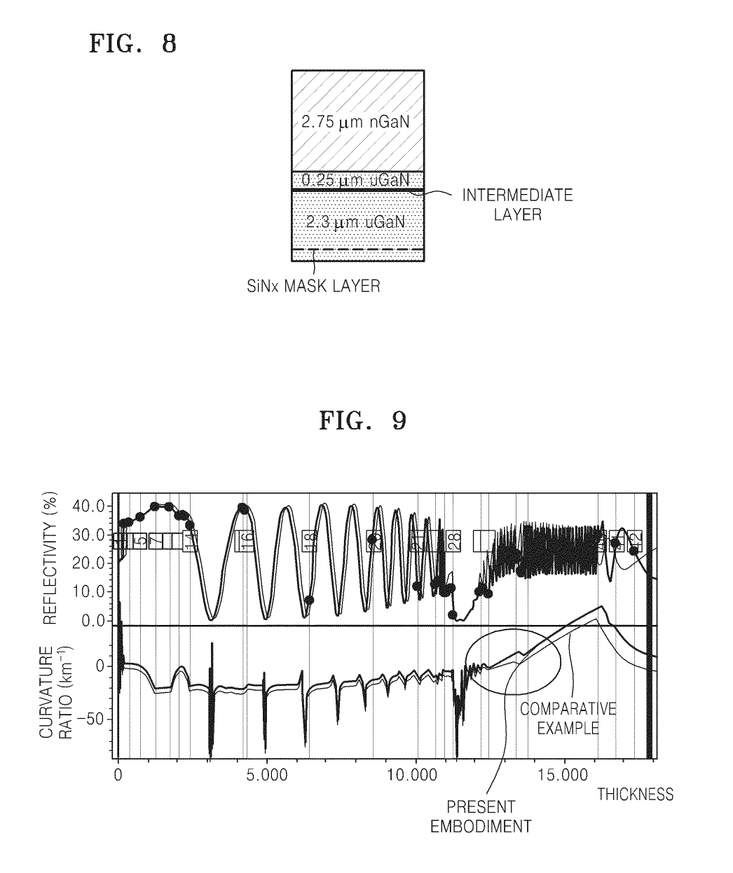

FIG. 6 shows an example embodiment of a semiconductor device which is compared to another device shown in FIG. 8. The semiconductor device in FIG. 6 has a stacked structure including a SiNx mask layer, a 1.15 μm uGaN, insertion layer, 1.15 μm uGaN layer, an intermediate layer, 0.25 μm uGaN, and a 2.75 μm nGaN layer. (Here, “uGaN” means undoped GaN and nGaN means an n-doped GaN). A scanning electron microscope (SEM) image showing a partial cross-section of the semiconductor device of FIG. 6 is shown in FIG. 7. In this image, the first 1.15 μm uGaN layer (corresponding to the first coalescent layer) has an uneven surface where merging was not completely performed on an upper portion thereof.

The semiconductor device of FIG. 8 has a stacked structure which omits the insertion layer of FIG. 6. More specifically, as shown, the device of FIG. 8 includes an SiNx mask layer, a 2.3 μm uGaN, and intermediate layer, a 0.25 μm uGaN layer, and a 2.75 μm nGaN layer. This structure has no insertion layer formed through the 2.3 μm uGaN layer, which is merged and grown using a mask layer.

FIG. 9 is a graph comparing in-situ curvature data and reflectivities produced when the structures shown in FIGS. 6 and 8 are grown using metal organic chemical vapor deposition (MOCVD). In this graph, a positive value curvature denotes a curvature that is convex upward due to the compressive stress, and a negative value curvature denotes a curvature that is convex upward due to the tensile stress. Also, in FIG. 9, the part denoted by a circle shows that the nitride semiconductor layer is merged and grown, and also shows that the compressive stress that is applied to the uGaN layer (corresponding to the second coalescent layer) behind the insertion layer is greater than the that of the comparative example. (In this non-limiting example, the entire stress on the semiconductor devices may be applied as compressive stress).

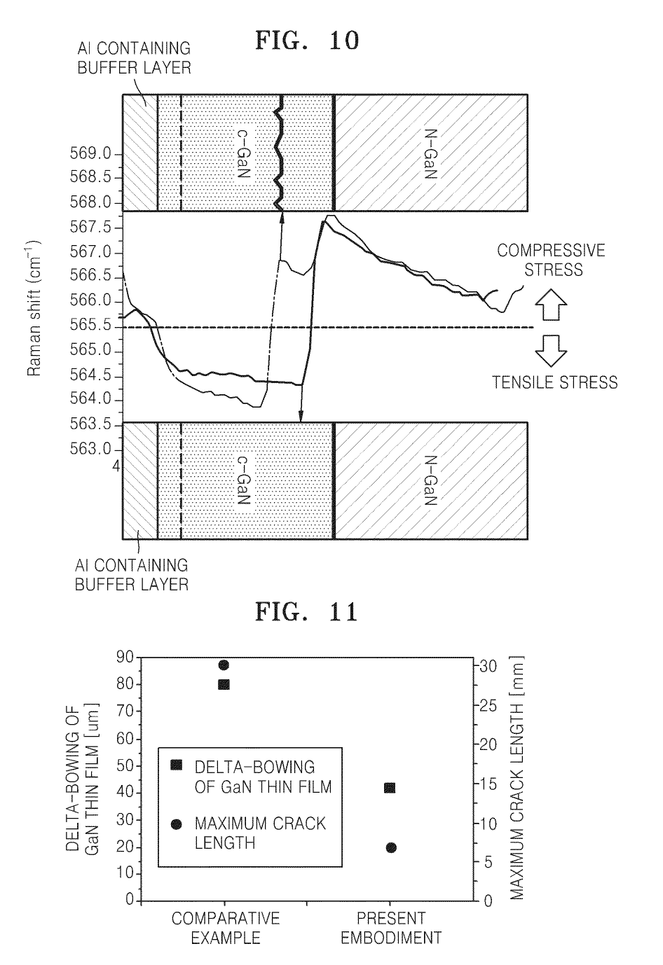

FIG. 10 is a graph comparing measured stress distributions for an example embodiment of the present invention (upper device) and another device (lower device). In the example embodiment, an insertion layer is disposed between two c-GaN layers. In FIG. 8 device, no insertion layer is included in its c-GaN layer. (“c-GaN” means a GaN layer formed by merged growth). This comparison was performed using a micro-Raman analysis method.

As shown in the graph, the entire portion of the c-GaN layer in the lower device has tensile stress applied thereto. However, in the example embodiment (upper device), tensile stress is only applied to one of the c-GaN layers and compressive stress is applied to the other c-GaN layer located above the insertion layer. The example embodiment, therefore, experiences less tensile stress and more compressive stress relative to the entire semiconductor device, which may reduce or prevent crack generation during the wafer bonding and/or the substrate removal stages.

Because the insertion layer is formed in the nitride semiconductor layer (or between two nitride layers) that is merged and grown, compressive stress may be generated without increasing the thickness of the merged nitride semiconductor layer during growth of the nitride semiconductor thin film. If the thickness of the merged nitride semiconductor layer increases, the portion to which the tensile stress is applied is increased and, thus, it is difficult to prevent cracks from being generated.

However, according to at least an example embodiment, the insertion layer may be formed without increasing the thickness of the merged nitride semiconductor layer, and thus tensile stress may be restrained.

Also, in order to increase crystallinity of the nitride semiconductor layer, one approach involves increasing the masking region formed by the mask layer and, in this case, the thickness of the coalescently grown nitride semiconductor layer and the portion that experiences tensile stress may also be increased.

However, according to the present embodiment, the insertion layer may allow compressive stress to be generated throughout all or a substantial portion of the coalescently grown nitride semiconductor layer of a same thickness. As a result, the entire tensile stress may be reduced and, thus, both a certain level of crystallinity and a reduction of crack formations may be simultaneously realized.

FIG. 11 is a graph that compares a delta bowing variation of a GaN layer and a maximum crack length at a boundary of a wafer after wafer bonding for an example embodiment and another device having no insertion layer. (Delta bowing means a difference between bowing in a state where a GaN thin film is grown and bowing in a state where a silicon substrate is removed after the wafer bonding. If the value of the delta bowing is large, a bending variation of the GaN thin film is increased, and thus cracks may be easily generated.)

For the devices compared in the graph, a wafer bonding process was performed by depositing Ti/Ni/Au on an epitaxial growth GaN thin film to 50 nm/100 nm/1500 nm, depositing sub-mount Ti/Ni/Au/Sn/Au to 50 nm/100 nm/80 nm/3800 nm/70 nm, performing wafer bonding at a pressure of 50000 N and a temperature of 280° C., and removing the silicon substrate. The above wafer bonding conditions are for an example in which the wafer has an 8″ diameter.

After performing this wafer bonding processes for the example embodiment and the other device under the same conditions, the bending variation amount of the GaN thin film (delta bowing) was measured. The bending variation amount of the GaN thin film in the other device was about 90 μm, and the bending variation amount of the GaN thin film in the example embodiment was substantially less, about 45 μm. Also, after removing the silicon substrate, the maximum crack length of the other device was about 30 mm and the maximum crack length of the example embodiment was about 6 mm or less.

In accordance with one or more embodiments described herein, an average compressive stress may be increased and tensile stress may be decreased. As a result of this decrease in tensile stress, the formation cracks may be reduced or altogether prevented. For example, generation of the cracks when the wafer bonding is performed on the grown nitride thin film or when the silicon substrate is removed may be reduced or prevented.

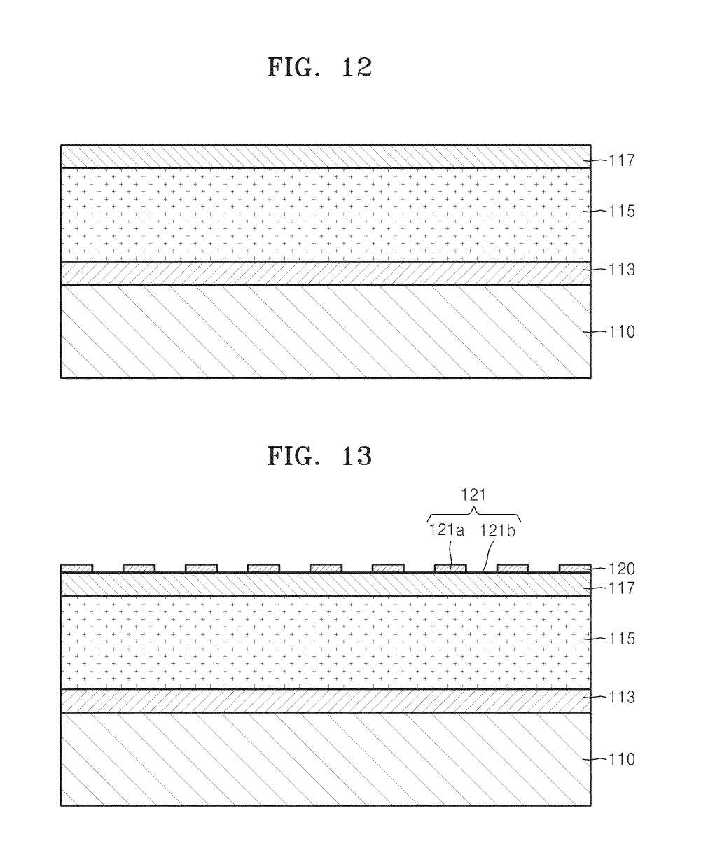

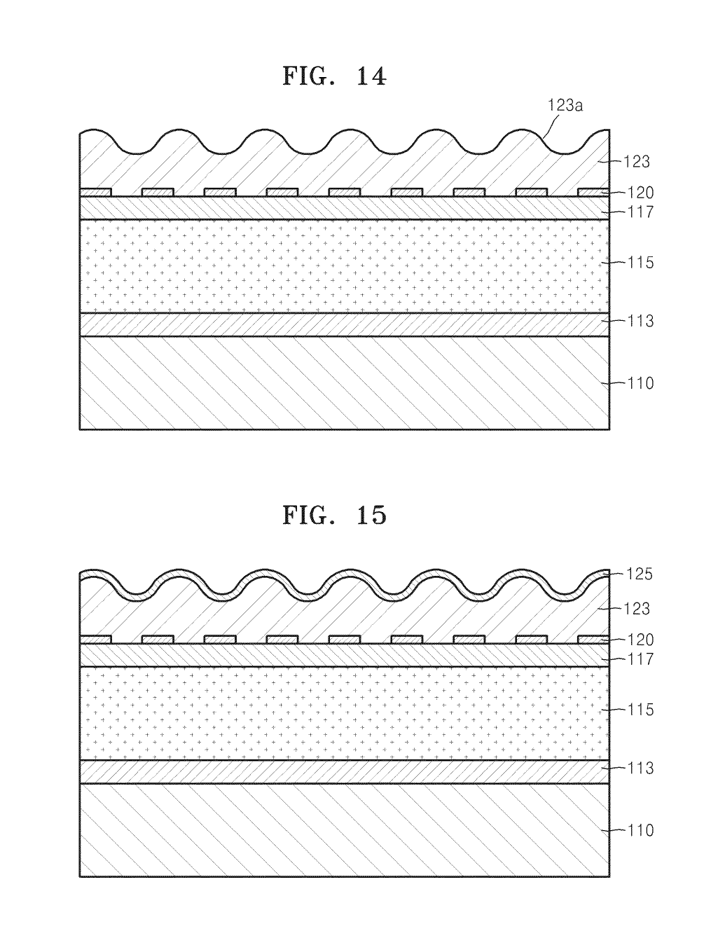

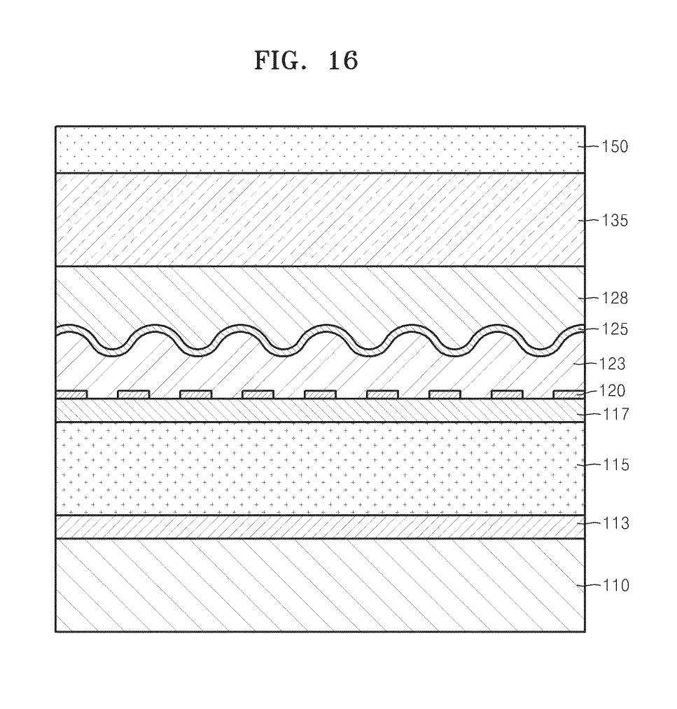

FIGS. 12 to 18 correspond to an example embodiment of a method for making a semiconductor device. In FIG. 12, a nuclear growth layer 113, a buffer layer 115, and a first nitride semiconductor layer 117 are formed on a substrate 110. The substrate 110 may be a silicon-based substrate, for example, a silicon substrate or a silicon carbide substrate. The nuclear growth layer 113 may be formed of, for example, AlN.

The buffer layer 115 may be formed of a material including one selected from the group consisting of AlN, AlGaN, step-grade AlₓIn_{y}Ga_{1-x-y}N (0≦x, y≦1, x+y≦1), and Alₓ₁In_{y1}Ga_{1-x1-y1}N/Alₓ₂In_{y2}Ga_{1-x2-y2}N (0≦x1, x2, y1, y2≦1, x1≠x2 or y1≠y2, x1+y1≦1, x2+y2≦1) super lattice. In this embodiment, one buffer layer 115 is formed. However, a plurality of buffer layers may be formed in other embodiments.

The first nitride semiconductor layer 117 may be formed of AlₓIn_{y}Ga_{1-x-y}N (0≦x, y≦1, x+y<1). For example, the nitride semiconductor layer may be formed of a material including at least one of GaN, InGaN, or AlInGaN.

In FIG. 13, a mask layer 120 is formed on the first nitride semiconductor layer 117. The mask layer 120 may include patterns 121, each including a masking region 121a and an open region 121b. The mask layer 120 may be formed to randomly and partially cover the nitride semiconductor layer, rather than completely covering the nitride semiconductor layer so as not to expose the nitride semiconductor layer. The degree of exposure of the nitride semiconductor layer is determined according to the coverage of the mask layer on the nitride semiconductor layer. The initial types of islands grown on the nitride semiconductor layer may vary. (The mask layer is shown to have a predetermined pattern for convenience of description. In other embodiments, the mask layer may have a different pattern from the one shown in FIG. 13). A coalescent layer is grown on the mask layer 120.

In FIG. 14, islands are formed on the open regions 121b and the islands are merged with each other due to the horizontal growth of the islands to form a first coalescent layer 123. The first coalescent layer 123 may have an uneven upper surface 123a, as the merging of the first coalescent layer 123 may be stopped before the islands are completely merged. In other embodiments, layer 123 may be allowed to completely merge.

An insertion layer 125 is formed on the uneven upper surface 123a. The insertion layer 125 may be formed, for example, of a material including at least one of a metal or a nitride. In an example embodiment, the insertion layer is made from a material that includes at least one of AlN, AlGaN, step-grade AlₓIn_{y}Ga_{1-x-y}N (0≦x, y≦1, x+y≦1), or a Alₓ₁In_{y1}Ga_{1-x1-y1}N/Alₓ₂In_{y2}Ga_{1-x2-y2}N (0≦x1, x2, y1, y2≦1, x1≠x2 or y1≠y2, x1+y1≦1, x2+y2≦1) super lattice.

In FIG. 16, a second coalescent layer 128 is grown on the insertion layer 125. The second coalescent layer 128 may have an even (e.g., planar or uniform) upper surface when the merging operation is finished. The first and second coalescent layers 123 and 128 may be formed of AlₓIn_{y}Ga_{1-x-y}N (0≦x, y≦1, x+y<1).

A nitride stacked structure 135 including at least one nitride semiconductor layer may be formed on the second coalescent layer 128. In addition, a wafer 150 is bonded on the nitride stacked structure 135. The wafer 150 may be a silicon-based wafer, for example, a silicon wafer. For example, the wafer bonding may be performed by using metal eutectic bonding. The wafer 150 may support the nitride thin film when the substrate 110 is removed.

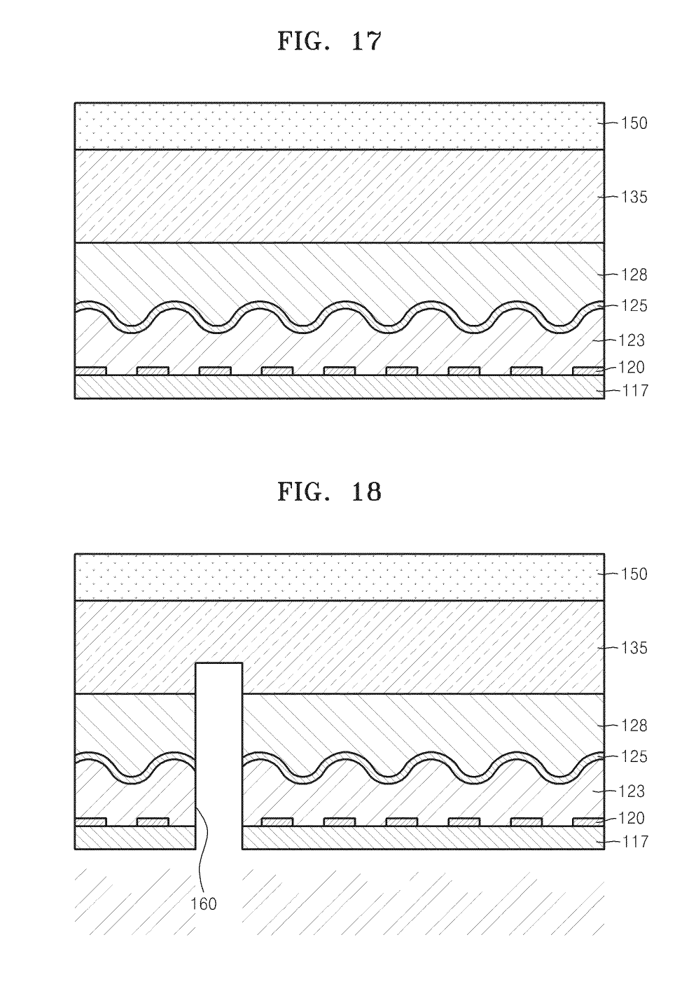

In FIG. 17, the substrate 110 is shown as having been removed after a wafer bonding process is performed. The substrate 110 may be removed along with the nuclear growth layer 113 and the buffer layer 115. During wafer bonding and/or substrate removal, cracks may be generated due to tensile stress. According to one or more embodiments, at least one insertion layer is formed in the coalescent layer to generate compressive stress and, thus, cracks may be reduced or prevented.

In FIG. 18, a via hole 160 is formed in the semiconductor device. The via hole 160 may be formed, for example, by etching a lower surface of the semiconductor device. When etching the via hole 160, the first and second coalescent layers and the nitride stacked substrate are exposed through the via hole 160, which provides an opportunity for cracks to be generated. However, cracks caused due to the etching may be prevented or reduced by the insertion layer 125.

Also, according to an example embodiment, a large-sized wafer may be manufactured by using a silicon substrate or a silicon carbide substrate for the semiconductor device. Example applications of the semiconductor device include the formation of light emitting diodes (LEDs), Schottky diodes, laser diodes, field effect transistors (FETs), power devices and various other analog or digital logic devices.

In one or more of the aforementioned embodiments, the first and second coalescent layers were disclosed to experience tensile and compressive stresses. In another embodiment, the stresses on the first and second coalescent layers may be different levels of tensile stress, with the second coalescent layer having less tensile stress. In embodiments which include three or more coalescent layers with intervening insertions layers, the second and third layers (e.g., 28 and 30 in FIG. 2) may experience or generate compressive stress, different types of stress, or different levels of the same stress by virtue of, for example, the materials of the insertion layers disclosed herein.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

1. A semiconductor device comprising:
a first nitride semiconductor layer;
a mask layer on the first nitride semiconductor layer;
a first coalescent layer including a plurality of partially merged islands;
a second coalescent layer on the first coalescent layer;
an insertion layer between the first and second coalescent layers; and
a nitride stacked structure on the second coalescent layer.

2. The semiconductor device of claim 1, wherein the mask layer comprises a silicon nitride material or a magnesium nitride material.

3. The semiconductor device of claim 1, wherein the first and second coalescent layers are formed of nitride semiconductor material.

4. The semiconductor device of claim 3, wherein each of the first and second coalescent layers are formed of at a material that includes at least one of a nitride or a metal.

5. The semiconductor device of claim 1, wherein at least one of the first coalescent layer or the second coalescent layer is made of a material that includes AlₓIn_{y}Ga_{1-x-y}N, where 0≦x, y≦1 and x+y<1.

6. The semiconductor device of claim 1, wherein the insertion layer is formed of at least one of Alₓ₀In_{y0}Ga_{1-x0-y0}N (0≦x0, y0≦1, x0+y0≦1), step-grade AlₓIn_{y}Ga_{1-x-y}N (0≦x, y≦1, x+y≦1), or Alₓ₁In_{y1}Ga_{1-x1-y1}N/Alₓ₂In_{y2}Ga_{1-x2-y2}N (0≦x1, x2, y1, y2≦1, x1≠x2 or y1≠y2) super lattice.

7. The semiconductor device of claim 1, wherein the insertion layer generates compressive stress in an area that includes at least the second coalescent layer.

8. The semiconductor device of claim 1, wherein the first coalescent layer has an uneven surface as a result of the partially merged islands.

9. The semiconductor device of claim 1, further comprising:
a buffer layer between the first nitride semiconductor layer and at least one of a substrate or a nuclear growth layer.

10. The semiconductor device of claim 9, wherein the buffer layer is made of a material that includes at least one of AlN, AlGaN, step-grade AlₓIn_{y}Ga_{1-x-y}N (0≦x, y≦1, x+y≦1), or a Alₓ₁In_{y1}Ga_{1-x1-y1}N/Alₓ₂In_{y2}Ga_{1-x2-y2}N (0≦x1, x2, y1, y2≦1, x1≠x2 or y1≠y2, x1+y1≦1, x2+y2≦1) super lattice.

11. The semiconductor device of claim 9, wherein the buffer layer is between the first nitride semiconductor layer and a nuclear growth layer.

12. The semiconductor device of claim 11, wherein the nuclear growth layer is made of a material that includes of AlN.

13. The semiconductor device of claim 11, wherein the substrate is disposed on the nuclear growth layer.

14. The semiconductor device of claim 13, wherein the substrate is made of a material that includes silicon or a silicon carbide.

15. The semiconductor device of claim 1, further comprising:
a third coalescent layer between the second coalescent layer and the nitride stacked structure; and
another insertion layer between the second and third coalescent layers.

16. The semiconductor device of claim 1, further comprising:
an intermediate layer between the second coalescent layer and the nitride stacked structure.

17. The semiconductor device of claim 1, wherein the intermediate layer is made of a material including at least one of Alₓ₀In_{y0}Ga_{1-x0-y0}N (0≦x0, y0≦1, x0+y0≦1), step-grade AlₓIn_{y}Ga_{1-x-y}N (0≦x, y≦1, x+y≦1), and a Alₓ₁In_{y1}Ga_{1-x1-y1}N/Alₓ₂In_{y2}Ga_{1-x2-y2}N (0≦x1, x2, y1, y2≦1, x1≠x2 or y1≠y2) super lattice.

18. The semiconductor device of claim 1, wherein:
the nitride stacked structure comprises a plurality of nitride semiconductor layers, and
at least one intermediate layer is disposed between two of the plurality of nitride semiconductor layers.

19. The semiconductor device of claim 1, wherein:
the insertion layer is disposed on the partially merged islands to allow a first type of stress to be generated in an area which includes the first coalescent layer and a second type of stress to be generated in an area which includes the second coalescent layer.

20. The semiconductor device of claim 19, wherein the first type of stress is opposite to the second type of stress.

21.-43. (canceled)
